(19) United States
(12) Patent Application Publication
(10) Pub. No.: US 2021/0043432 A1
(43) Pub. Date: Feb. 11, 2021

(54) SUBSTRATE SUPPORT SYSTEM

(71) Applicant: Applied Materials, Inc., Santa Clara, CA (US)

(72) Inventors: John MAZZOCCO, San Jose, CA (US); Keith A. MILLER, Mountain View, CA (US); Alexander ERENSTEIN, San Jose, CA (US); Ilya LAVITSKY, San Francisco, CA (US)

(21) Appl. No.: 16/986,036

(22) Filed: Aug. 5, 2020

Related U.S. Application Data
(60) Provisional application No. 62/883,234, filed on Aug. 6, 2019.

(51) Int. Cl. H01J 37/32; H01J 37/34; C23C 14/34; C23C 14/50

(52) U.S. Cl. CPC H01J 37/32715; H01J 37/3447; H01J 2237/20285; C23C 14/50; C23C 14/34

(57) ABSTRACT

A support system for use in a processing chamber is provided. The support system includes two or more moveable substrate supports, which include a substrate support surface and a robot, wherein the robot is configured to move the substrate support surface along a movement path. The substrate support includes a halo, and the halo protects the underlying components of the processing chamber from unwanted deposition, while the substrate support surface is moving along the movement path. The substrate support protects processing chamber components from deposition, reducing cleaning time and reducing the need for repairs of the components of the processing chamber.

### CROSS-REFERENCE TO RELATED APPLICATIONS

This application claims priority to U.S. Provisional Patent Application No. 62/883,234, filed Aug. 6, 2019, which is hereby incorporated by reference in its entirety.

### BACKGROUND

### Field

Embodiments of the invention relate to an apparatus and, more specifically, a substrate support system.

### Description of the Related Art

Integrated circuits (IC) may include more than one million micro-electronic devices such as transistors, capacitors, and resistors. Modern ICs are manufactured in processing chambers using a multitude of steps, such as sputter deposition. Sputter deposition is a physical vapor deposition (PVD) method of thin film deposition by sputtering, which involves ejecting material from a target onto a substrate, such as a silicon wafer. Sputtered atoms ejected from the target have a wide energy distribution, typically up to tens of eV. The sputtered ions can ballistically fly from the target in straight lines and impact energetically on the substrates within the processing chamber, on the walls of the processing chamber, or on other components of the processing chamber.

Sputtering is used extensively in the semiconductor industry to deposit thin films of various materials in IC processing. Thin antireflection coatings on glass for optical applications are also deposited by sputtering. Because of the low substrate temperatures used, sputtering is an ideal method to deposit contact metals for thin-film transistors. Another familiar application of sputtering is low-emissivity coatings on glass, used in double-pane window assemblies. The coating is a multilayer containing silver and metal oxides such as zinc oxide, tin oxide, or titanium dioxide.

However, due to the high energies of the sputtered ions, redeposition is an unfortunate side effect of a standard sputtering process, in which scattered sputtered ions form redeposits in areas of the processing chamber beside the substrate. For example, unwanted redeposits can form on chamber components, causing damage and necessitating frequent cleaning, which increases cost of ownership for the user. In addition, redeposits formed on chamber walls and the chamber ceiling can fall on the substrate, causing problems with the intended IC layer growth on the substrate through electrical shorts. Redeposits can also form on the back of the substrate, interfering with proper functioning of the device eventually created from the substrate. Finally, systems with multiple substrate supports need additional features that prevent scattered material from entering gaps or cracks between the substrate supports, redepositing on the machinery below.

Therefore, there is a need for a substrate support system that helps shield the remainder of the processing chamber from unwanted redeposits.

### SUMMARY

In one embodiment, a support system for use in a processing chamber is provided, including two support structures. Each of the support structures include a substrate support surface, a ring, and a halo. The substrate support surface is surrounded by the ring. The halo at least partially surrounds the ring. The halo includes a top surface and a halo flange. The halo flange includes a halo flange surface. The distance between the halo flange surface and the substrate support surface is greater than the distance between the top surface and the substrate support surface.

In another embodiment, a moveable substrate support system is provided, including two moveable substrate supports. Each of the moveable substrate supports include a support structure, a robot arm connected to the support structure, and a robot actuator connected to the robot arm. The support structure includes a substrate support surface, a ring surrounding the substrate support surface, and a halo. The halo at least partially surrounds the ring. The halo includes a top surface and a halo flange including a halo flange surface. The distance between the halo flange surface and the substrate support surface is greater than the distance between the top surface and the substrate support surface. The robot actuator is configured to move the robot arm and the support structure along a movement path.

In another embodiment, a processing chamber is provided, including a moveable substrate support system, a top chamber surface having an aperture disposed therethrough, one or more chamber walls, and a chamber bottom. An interior volume is at least partially bounded by the top chamber surface, one or more chamber walls, and the chamber bottom. The moveable substrate support system includes two moveable substrate supports. Each of the moveable substrate supports are disposed within the interior volume. The moveable substrate support includes a support structure, a robot arm connected to the support structure, and a robot actuator connected to the robot arm. The support structure includes a substrate support surface, a ring surrounding the substrate support surface, and a halo. The halo at least partially surrounds the ring. The halo includes a top surface and a halo flange including a halo flange surface. The distance between the halo flange surface and the substrate support surface is greater than the distance between the top surface and the substrate support surface. The robot actuator is configured to move the robot arm and the support structure along a movement path.

Features of the support system, such as halos, prevent redeposition of sputtered ions onto undesired portions of the processing chamber and the backside of the substrate. Other features of the support system, such as grooves and gaps, help trap ricocheting ions at the support structure, and thus the ions do not redeposit and cause breakdowns of other components in the processing chamber, which reduces cleaning and other costs of ownership.

### BRIEF DESCRIPTION OF THE DRAWINGS

So that the manner in which the above-recited features of the present disclosure can be understood in detail, a more particular description of the embodiments, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a schematic top view of a processing platform, according to one embodiment

FIG. 1B illustrates an isometric top side view of a processing chamber, according to one embodiment.

FIG. 1C illustrates an isometric top side view of a chamber body, according to one embodiment.

FIGS. 1D-1E illustrate schematic side views of the processing chamber of FIG. 1B, according to one embodiment.

FIG. 1F illustrates a schematic side view of a processing chamber for vertical deposition, according to one embodiment.

FIGS. 2A-B illustrates deposition of material in a semiconductor feature, according to one embodiment.

FIG. 3A illustrates a schematic side view of a support structure with a substrate disposed on the support structure, according to one embodiment.

FIG. 3B illustrates a schematic side view of a portion of a halo, according to one embodiment.

FIG. 3C illustrates a schematic side view of a portion of a ring, according to one embodiment.

FIG. 3D illustrates a schematic side view of an interlocking system, according to one embodiment.

FIG. 4A illustrates a schematic side view of the support structure with a shutter disk disposed on the support structure, according to one embodiment.

FIG. 4B illustrates a schematic side view of a portion of the substrate support surface, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure provided herein include a support system that protects the remainder of the processing chamber and the components of the processing chamber from redeposition. Two or more moveable substrate supports are configured to move past an aperture in the processing chamber, which results in deposition on the substrate at an angle. The support structures include halos, and the halos block sputtered ions from deposition during motion of the moveable substrate support system. The halos of adjacent substrate supports can interlock with an interlocking system. Features in the support structure minimize redeposition by containing redeposits in localized parts of the support structure, preventing redeposition of material in components of the processing chamber. Embodiments of the disclosure provided herein may be especially useful for, but are not limited to, a support system that reduces redeposition in a processing chamber.

As used herein, the term “about” refers to a +/−10% variation from the nominal value. It is to be understood that such a variation can be included in any value provided herein.

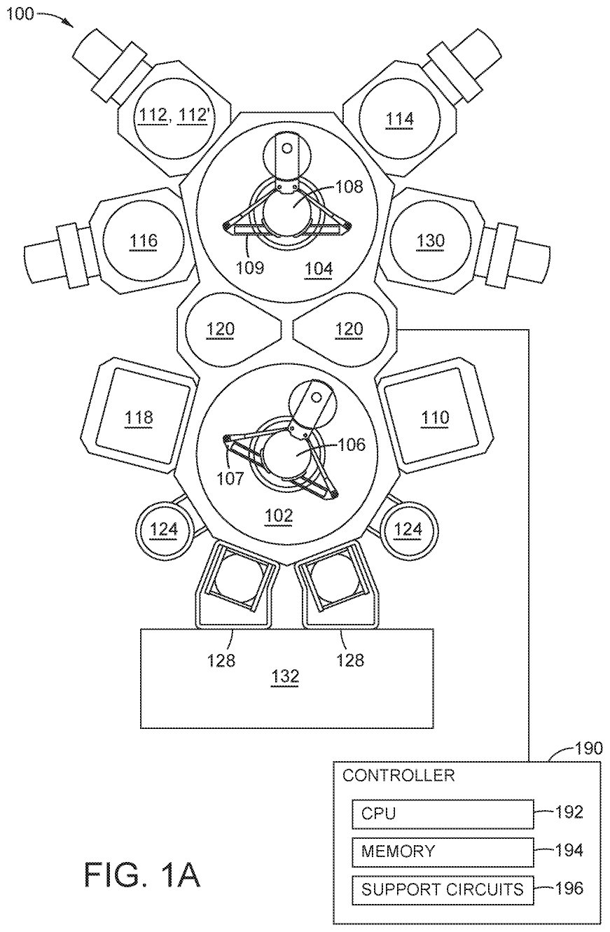

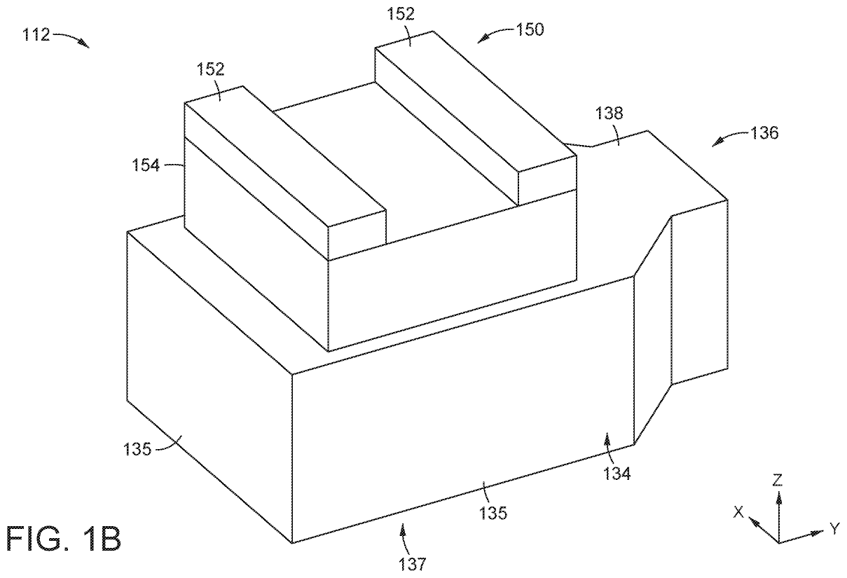

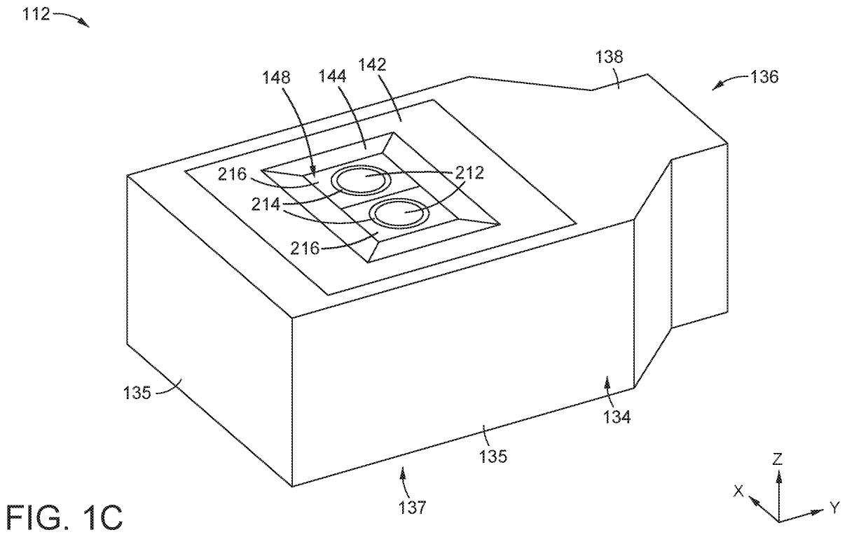

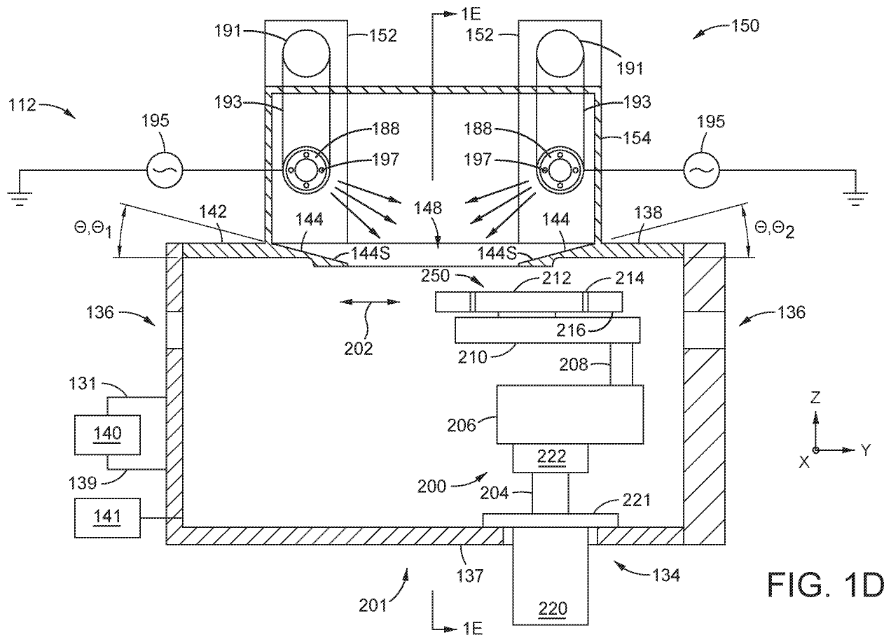

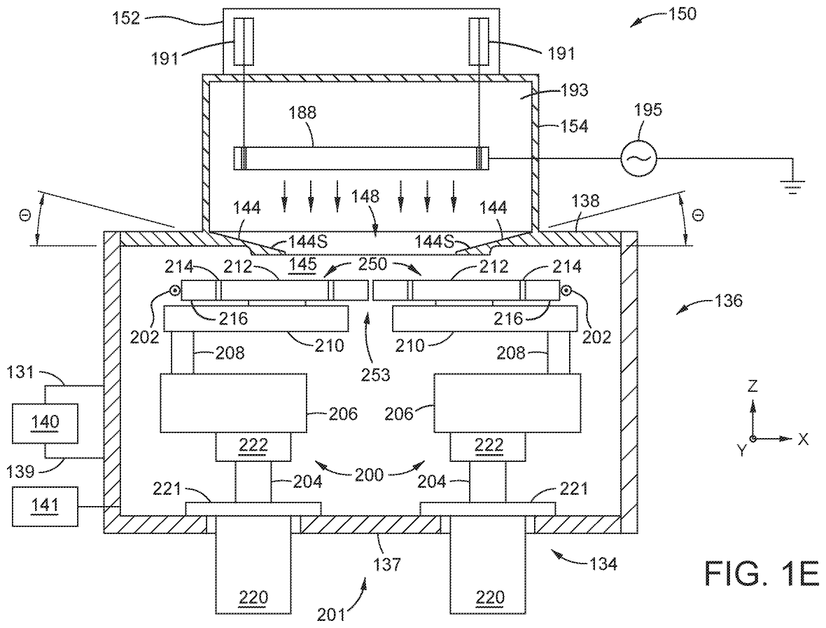

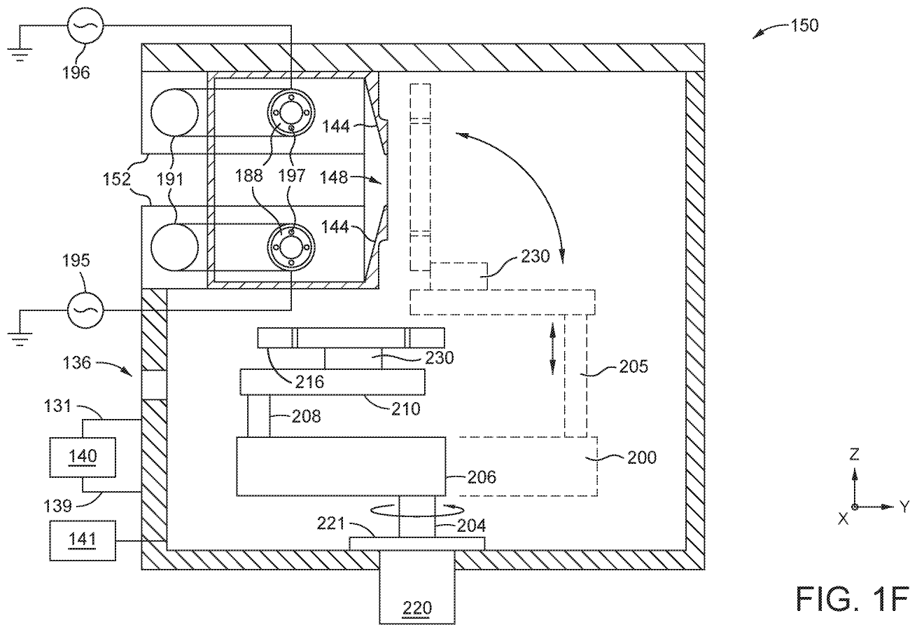

FIG. 1A illustrates a schematic top view of a processing platform 100, according to one embodiment. As shown, the processing platform 100 includes two transfer chambers 102, 104, transfer robots 106, 108 positioned in the transfer chambers 102, 104, respectively, and processing chambers 110, 112, 112′, 114, 116, 118, 130 disposed on the two transfer chambers 102, 104. The first and second transfer chambers 102, 104 are central vacuum chambers that interface with adjacent processing chambers 110, 112, 112′, 114, 116, 118, 130. The first transfer chamber 102 and the second transfer chamber 104 are separated by pass-through chambers 120, which can include cooldown or pre-heating chambers. The pass-through chambers 120 also can be pumped down or ventilated during substrate handling when the first transfer chamber 102 and the second transfer chamber 104 operate at different pressures. For example, the first transfer chamber 102 can operate between about 100 mTorr and about 5 Torr, such as about 40 mTorr, and the second transfer chamber 104 can operate between about 1×10⁻⁵ Torr and about 1×10⁻¹⁰ Torr, such as about 1×10⁻⁷ Torr.

The first transfer chamber 102 is coupled with two degas chambers 124, two load lock chambers 128, chemical vapor deposition (CVD) or rapid thermal processing (RTP) chambers 110, 118, and the pass-through chamber 120. Substrates (not shown) are loaded into the processing platform 100 through load lock chambers 128. For example, a factory interface module 132, if present, would be responsible for receiving one or more substrates, e.g., wafers, cassettes of wafers, or enclosed pods of wafers, from either a human operator or an automated substrate handling system. The factory interface module 132 can open the cassettes or pods of substrates, if applicable, and move the substrates to and from the load lock chambers 128. The processing chambers 110, 112, 112′, 114, 116, 118, 130 receive the substrates from the transfer chambers 102, 104, process the substrates, and allow the substrates to be transferred back into the transfer chambers 102, 104.

Each of the processing chambers 110, 112, 112′, 114, 116, 118, 130 is isolated from the transfer chambers 102, 104 by an isolation valve which allows the processing chamber to operate at a different level of vacuum than the transfer chambers 102, 104 and prevents any gases being used in the processing chamber from being introduced into the transfer chambers 102, 104. The load lock chambers 128 are also isolated from the transfer chamber 102, 104 with isolation valves. Each load lock chamber 128 has a door which opens to the outside environment, e.g., opens to the factory interface module 132. In normal operation, a cassette loaded with substrates is placed into the load lock chamber 128 through the door from the factory interface module 132 and the door is closed. The load lock chamber 128 is then evacuated to the same pressure as the transfer chamber 102 and the isolation valve between the load lock chamber 128 and the transfer chamber 102 is opened. The transfer robot 106 in the transfer chamber 102 is moved into position and one substrate is removed from the load lock chamber 128. The load lock chamber 128 is preferably equipped with an elevator mechanism so as one substrate is removed from the cassette, the elevator moves the stack of substrates in the cassette to position another substrate in the transfer plane so that it can be positioned by the transfer robot 106.

The transfer robot 106 in the transfer chamber 102 then rotates with the substrate so that the substrate is aligned with a processing chamber position. The processing chamber is flushed of any toxic gases, brought to the same pressure level as the transfer chamber, and the isolation valve is opened. The transfer robot 106 then moves the substrate into the processing chamber where it is removed from the transfer robot 106. The transfer robot 106 is then retracted from the processing chamber and the isolation valve is closed. The processing chamber then goes through a series of operations to execute a specified process on the substrate. When complete, the processing chamber is brought back to the same environment as the transfer chamber 102 and the isolation valve is opened. The transfer robot 106 removes the substrate from the processing chamber and then either moves it to another processing chamber for another operation or replaces it in the load lock chamber 128 to be removed from the processing platform 100 when the entire cassette of substrates has been processed.

The transfer robots 106, 108 include robot arms 107, 109, respectively, that support and move the substrate between different processing chambers. Although only one robot arm 109 is shown, it is understood that any number of robot arms can be included. For example, if processing chamber 112, 112′ is configured to process more than one substrate at a time, then a robot 109 can be included for each substrate to be processed, and the robots can move multiple substrates into the same processing chamber simultaneously. The transfer robot 106 moves the substrate between the degas chambers 124 and the processing chambers 110, 118 for deposition of a material thereon.

The second transfer chamber 104 is coupled to a cluster of processing chambers 112, 112′, 114, 116, and 130. The processing chambers 112, 112′, 114, 116, and 130 are physical vapor deposition (PVD) chambers for depositing materials, according to one embodiment. The CVD-processed substrates are moved from the first transfer chamber 102 into the second transfer chamber 104 via the pass-through chambers 120. Thereafter, the transfer robot 108 moves the substrates between one or more of the processing chambers 112, 112′, 114, 116, 130 for material deposition and annealing as required for processing.

RTA chambers (not shown) can also be disposed on the first transfer chamber 102 of the processing platform 100 to provide post deposition annealing processes prior to substrate removal from the platform 100 or transfer to the second transfer chamber 104.

While not shown, a plurality of vacuum pumps is disposed in fluid communication with each transfer chamber and each of the processing chambers to independently regulate pressures in the respective chambers. The pumps can establish a vacuum gradient of increasing pressure across the apparatus from the load lock chamber to the processing chambers.

Alternatively or in addition, a plasma etch chamber, such as a Decoupled Plasma Source chamber (DPS™ chamber) manufactured by Applied Materials, Inc., of Santa Clara, Calif., can be coupled to the processing platform 100 or in a separate processing system for etching the substrate surface to remove unreacted metal after PVD metal deposition and/or annealing of the deposited metal. For example, in forming cobalt silicide from cobalt and silicon material by an annealing process, the etch chamber can be used to remove unreacted cobalt material from the substrate surface.

Other etch processes and apparatus, such as a wet etch chamber, can be used in conjunction with the process and apparatus described herein.

A controller 190, such as a programmable computer, is connected to the processing platform 100 to control the movement of the robots 106, 108 and the motion of the substrate between the various processing chambers 110, 112, 112′, 114, 116, 118, 130, and the two transfer chambers 102, 104. The controller 190 can include a central processing unit (CPU) 192, a memory 194, and support circuits 196, e.g., input/output circuitry, power supplies, clock circuits, cache, and the like. The memory 194 is connected to the CPU 192. The memory 194 is a non-transitory computer readable medium, and can be one or more readily available memory such as random access memory (RAM), read only memory (ROM), floppy disk, hard disk, or other form of digital storage. In addition, although illustrated as a single computer, the controller 190 could be a distributed system, e.g., including multiple independently operating processors and memories. This architecture is adaptable to various embodiments of the processing platform 100 based on programming of the controller 190 to control the order and timing of the movement of the substrate to and from the chambers. In addition, the controller 190 also controls various process variables in each of the processing chambers 110, 112, 112′, 114, 116, 118, 130 and transfer chambers 102, 104, such as temperature, pressure and the like.

FIG. 1B illustrates an isometric top side view of processing chamber 112, according to one embodiment. As shown, processing chamber 112 includes a source assembly 150 and a chamber body 134. The source assembly 150 is separable from the chamber body 134. The source assembly 150 can be removed from the chamber body 134, in order to access an aperture 148 (FIG. 1C). The source assembly 150 is secured to the chamber body 134 during operation of the processing chamber 112.

FIG. 1C illustrates an isometric top side view of the chamber body 134, according to one embodiment. As shown, the chamber body 134 includes a top chamber surface 138, a top panel 142, two moveable substrate supports 200, a slot 136, a sloped portion 144, and an aperture 148. The chamber body 134 contains the interior volume 145 that is at least partially bounded by the top chamber surface 138 above, chamber walls 135, and chamber bottom 137 of the chamber body 134. The slot 136 is disposed in the side of the chamber body 134, which allows for motion of a substrate into and out of the chamber body.

The top chamber surface 138 can include the top panel 142. The top panel 142 is separable from the top chamber surface 138, according to one embodiment. A separable top panel 142 allows for easier cleaning of the removed top panel, instead of needing to clean the top panel while still installed in the chamber body 134. The top chamber surface 138 includes the aperture 148. The top chamber surface 138 includes the sloped portion 144, where the sloped portion at least partially surrounds the aperture 148. The top chamber surface 138, the top panel 142, and the sloped portion 144 can all be one solid piece, or top chamber surface, top panel, and sloped portion can all be separate pieces.

FIGS. 1D-1E illustrate schematic side views of the processing chamber 112 of FIG. 1B, according to one embodiment. As shown, source assembly 150 includes a plurality of pulley guards 152, a plurality of pulleys 191, a plurality of belts 193, a source 154 enclosing a plurality of targets 188 therein, a plurality of target magnets 197, and a plurality of target power sources 195. The material of the targets 188 includes a metal or a semiconductor. The interior of the source 154 is held at vacuum pressures. The material of the targets 188 includes titanium (Ti), according to one embodiment. The material of the targets 188 includes silicon (Si), according to one embodiment. The targets 188 can include metals, e.g., copper, aluminum, tantalum, cobalt, or any alloy of the same. The targets 188 can include a dielectric material. The targets 188 include the plurality of target magnets 197. The plurality of target magnets 197 can be a fixed field magnetic strength, and each magnet can be a different magnetic field strength. The target magnets 197 are electromagnets, and can be powered by the target power sources 195, according to one embodiment. The target power sources 195 can be located in the source assembly 150, or outside the source assembly. The powered target magnets 197 cause sputtering of the targets 188 through an electromagnetic interaction, which deposits material from the targets on a substrate through the aperture 148 below.

The targets 188 are cylindrical, according to some embodiments. The targets 188 can be connected to the pulleys 191 by the belts 193, and the targets can be rotated during sputtering, according to one embodiment. The rotation of the targets 188 results in a more even erosion of the material from the targets onto a substrate positioned below. The pulleys 191 are protected from the outside environment by the pulley guards 152. The pulley guards 152 protect the pulleys 191 from damage during assembly, disassembly, or functioning of the processing chamber 112. The targets 188 are rectangular, according to some embodiments.

In some embodiments, a process gas is flowed during the sputtering process, and at least some of the process gas reacts with the sputtered material. In one embodiment, the process gas includes nitrogen gas (N₂), the material of the targets 188 includes Ti, and the material deposited on the substrate includes titanium nitride (TiN). In one embodiment, the process gas includes nitrogen gas (N₂), the material of the targets 188 includes Si, and the material deposited on the substrate includes silicon nitride (SiN). The process gas can include a neutral gas, such as helium (He) or argon (Ar). The neutral gas maintains the desired pressure of the process gas. The neutral gas can also sputter material from the targets 188 through ballistic interaction with the material of the target.

The top surface 144S of the sloped portion 144 is at an angle θ to the X-direction and the Y-direction, wherein the X-direction and Y-direction are substantially parallel to the top chamber surface 138. The angle θ ranges from about greater than 0° to about less than 90°, such as about 15° to about 35°, according to one embodiment. Deposition spray from the target 188 only deposits on the substrate 310 at angles larger than the angle θ. Different portions of the sloped portion 144 can have different angles, such as θ₁ and θ₂, as pictured in FIG. 1D.

The aperture 148 and the sloped portion 144 can be disposed in the top panel 142 if the top panel is present. The aperture 148 can be any desired shape. The aperture 148 is rectangular, according to one embodiment. The aperture 148 is hourglass shaped, according to another embodiment. The top panel 142 can be swapped out for different deposition methods, with the shape of the aperture 148, the size of the aperture 148, and the angle θ of the sloped portion 144 varied with the desired deposition process. The chiller pump 140 supplies water or another fluid to the chamber 112 via supply plumbing 131 and from the chamber via return plumbing 139. The chiller pump 140 supplies water or another fluid to the top panel 142, providing cooling to the top panel and keeping the top panel at the desired temperature. The temperature of the top panel can be controlled from about −20° C. to about 100° C. In one embodiment, the top panel 142 includes aluminum (Al), and the fluid cooling prevents overheating of the top panel 142, and minimizes peeling and flaking of the deposition material. A vacuum pump 141 is connected to the chamber 112, and the vacuum pump removes unwanted byproducts and exhaust from the processing chamber.

As shown, the moveable substrate support system 201 includes two or more moveable substrate supports 200. As shown, the moveable substrate support 200 includes a support actuator 220, a mounting flange 221, a support shaft 204, a robot actuator 222, a robot arm 206, a shaft 208, a robot wrist 210, and a support structure 250. The moveable substrate support 200 is disposed in the interior volume 145. The support actuator 220 is mounted to the chamber bottom 137 by the mounting flange 221. The support actuator 220 is connected to the support shaft 204. The support actuator 220 is configured to move the support shaft 204 vertically, which moves the rest of the moveable substrate support 200 vertically. The robot actuator 222 is attached to the support shaft 204. The robot arm 206 is connected to the robot actuator 222. The robot actuator 222 is configured to move the robot arm 206 horizontally. The shaft 208 is connected to the robot arm 206. The shaft 208 supports the robot wrist 210. The robot wrist 210 supports the support structure 250. The combination of vertical motion from the support actuator 220 and horizontal motion of the robot actuator 222 allows for moving the support structure 250 in three-dimensional space.

As shown, the support system 253 includes two or more support structures 250. A substrate can be placed on each of the support structures 250. Transfer robots 106, 108 are configured to move the substrate from outside the chamber 112 into the chamber through slot 136. The moveable substrate supports 200 are configured to move the substrates from the slot 136 to near the aperture 148 for sputtering of material onto the substrate. In some embodiments, the slot 136 is not at an ideal vertical position for sputtering onto the substrate, and the moveable substrate support 200 moves the substrate higher or lower than the slot 136 to begin deposition. Different areas of the substrate that are not currently exposed by the aperture 148 can be reached by moving the support structure 250 horizontally and/or vertically during deposition processes.

As shown, the support structure 250 includes a substrate support surface 212, a ring 214, and a halo 216. The substrate support surface 212 is supported by the robot wrist 210. The substrate support surface 212 can include any material used in an electrostatic chuck. The substrate support surface 212 includes a ceramic material, e.g., aluminum oxide or boron nitride, according to one embodiment. The substrate support surface 212 can include metal, e.g., stainless steel. The substrate support surface 212 secures the substrate to the support structure 250. The ring 214 surrounds the substrate support surface 212, and the ring is connected to the robot wrist 210. The ring 214 can include a metal, such as, e.g., stainless steel, titanium, low coefficient of thermal expansion (CTE) alloys, or aluminum beryllium alloys. The halo 216 at least partially surrounds the ring 214, and the halo is connected to the ring 214. The halo 216 includes a metal, such as, e.g., stainless steel, titanium, low CTE alloys, or aluminum beryllium alloys. The halo 216 includes a pattern or stiffening elements that reduces strain in the halo. The pattern or stiffening elements can be indentations in the halo, such as an X or cross shape. The dimensions of the halo 216 are such that the aperture 148 is completely blocked by the support structure 250. The halo 216 prevents unwanted deposition of material on the other components of the moveable substrate support 200 below. The combination of the aperture 148 and halo 216 prevent deposition into the chamber 112, while still allowing deposition onto substrate 310.

The support structure 250 can include a heater (not shown), a cooling apparatus (not shown), for example, a water cooling system, or both. The heater and/or the cooling apparatus controls the temperature of the support structure and the substrate disposed on the support structure to temperatures between about −20° C. and about 400° C., according to one embodiment. The support structure 250 includes an electrostatic chuck (ESC) (not shown), and the substrate is chucked to the ESC, according to one embodiment. The ESC provides an applied voltage to the substrate disposed on the support structure 250, according to one embodiment. The support structure 250 includes ports configured to provide a backside gas (not shown), and the backside gas is provided to the substrate, according to one embodiment. The backside gas can include a neutral gas, such as argon gas (Ar) or helium gas (He), according to one embodiment.

During sputtering, the moveable substrate support 200 moves the substrate along a movement path 202. The movement path 202 can be any direction or path in real space. For example, the movement path 202 can be substantially in the x direction, substantially in the y direction, or both. The movement path 202 can be a smooth motion without pauses, or the movement path can include portions of the path wherein the support structure 250 is stationary. The movement path 202 is a linear movement as shown in FIGS. 1D-1E, according to one embodiment. The movement path can be one direction, a back and forth direction, or containing multiple passes, according to some embodiments. The movement path 202 is a circular rotation about the aperture 148, according to one embodiment. The movement path 202 is such that the substrate support surface 212 is under the aperture 148 for at least a portion of the movement path. The movement path 202 is such that the substrate support surface 212 is not under the aperture 148 for at least a portion of the movement path, and at least a portion of the halo 216 is under the aperture for at least a portion of the movement path.

The moveable substrate supports 200 can be moved in concert, or they can be moved separately. The moveable substrate supports 200 can be moved at the same speed, or at different speeds, depending on the film desired. Moving the moveable substrate supports 200 along the substantially same movement path 202 allows for doubling of the throughput of substrate processing, as films can be deposited on two or more substrates at the same speed as one substrate. In addition, using two or more moveable substrate supports 200 in a single processing chamber 112 is preferable to using multiple processing chambers with one moveable substrate support, as pump systems, gas systems, and power systems are needed only for a single processing chamber.

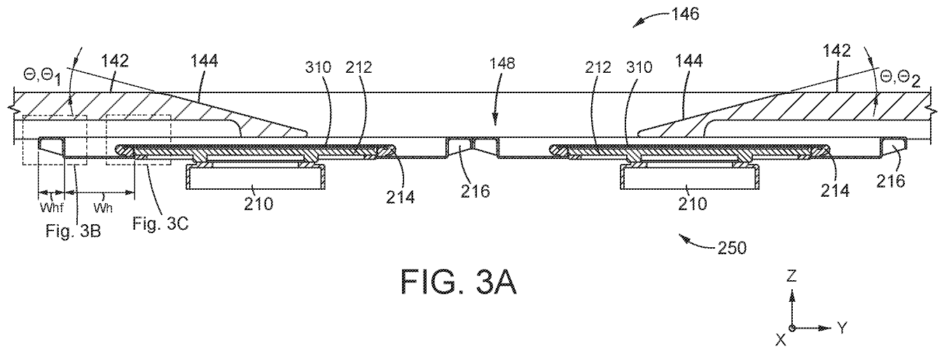

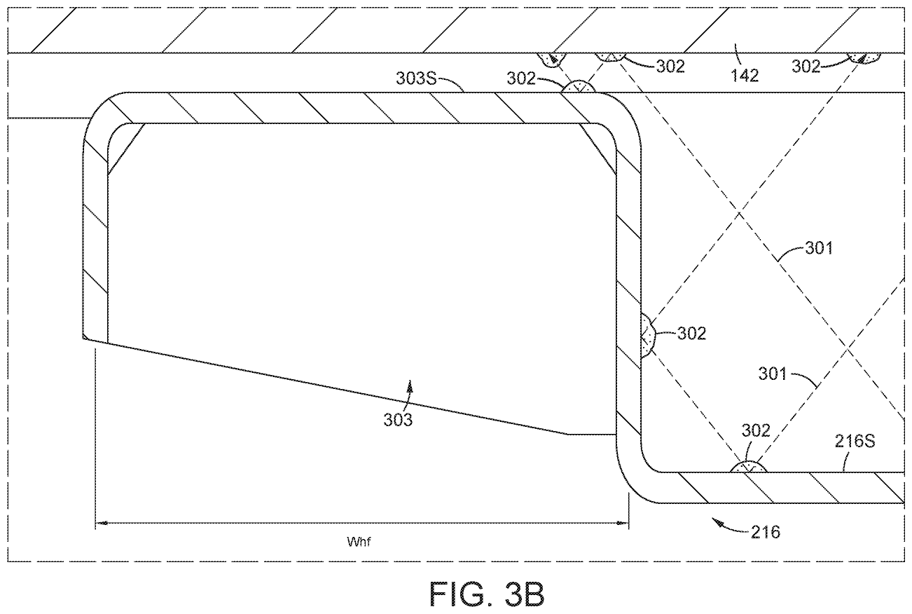

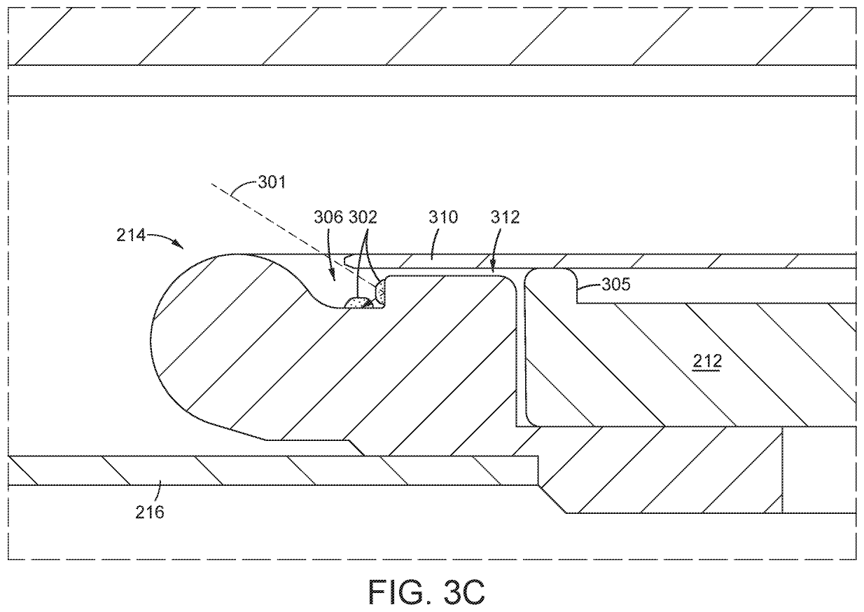

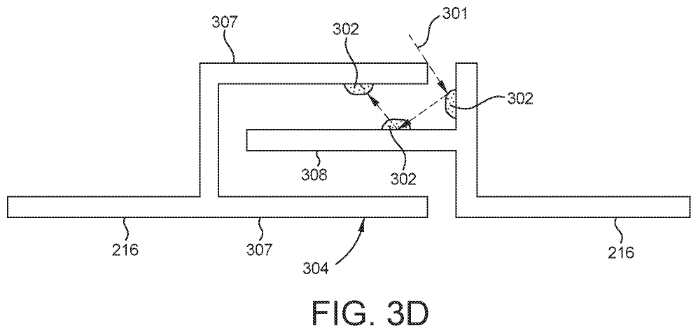

The moveable substrate supports 200 are interlocked with one another with an interlocking system 304, according to some embodiments (FIG. 3D). The moveable substrate supports 200 are interlocked with one another with an interlocking system 304 during at least a portion of the movement path 202, according to one embodiment. For example, the moveable substrate supports 200 can each accept a substrate from outside the processing chamber 112, the moveable substrate supports move toward one another from the x direction, the moveable substrate supports 200 interlock with one another with the interlocking system 304, and the moveable substrate supports move in the y direction while interlocked during the deposition. The interlocking of the moveable substrate supports 200 reduces unwanted deposition in spaces between the halos of 216 onto the machinery below.

FIG. 1F illustrates a schematic side view of a processing chamber 112′ for vertical deposition, according to one embodiment. The processing chamber 112′ is similar to the processing chamber 112 above, but the processing chamber 112′ is configured for vertical deposition on the substrate, i.e. the substrate is held vertically, and the deposition occurs from the side of the chamber in direction y. In this embodiment, the moveable substrate supports 200 further include a rotation actuator 230. Although only one moveable substrate support 200 is shown, it is to be understood that the other moveable substrate support is behind the depicted moveable substrate support, and the moveable substrate supports move in parallel. The rotation actuator 230 rotates the support structure 250 such that the substrate is oriented vertically, i.e. with the support structure facing in the y direction. The support structure 250 further includes an ESC, in order to keep the substrate from dropping off of the support structure. The vertically aligned process chamber 112′ takes up less floor width than the traditional embodiment.

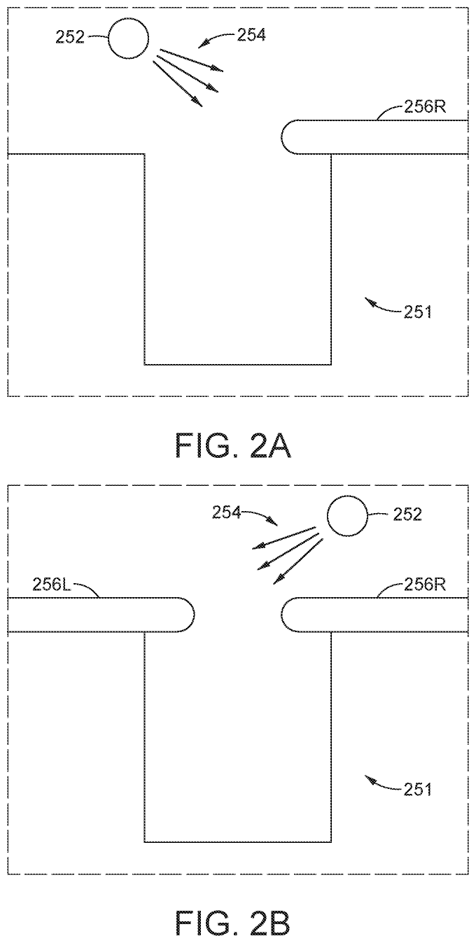

FIG. 2A illustrates deposition of material in a semiconductor feature 251, according to one embodiment. Sputtering source 252 sputters material spray 254 toward the semiconductor feature 251 through the aperture 148. In the illustration of FIG. 2A, the semiconductor feature 251 is located to the right of the source 252, and deposition 256R is only grown on the right side of the semiconductor feature, as the left side of the semiconductor feature is covered by the top panel 142. The sputtering source 252 can be the target 188 as described above.

FIG. 2B illustrates deposition of material in a semiconductor feature 251, according to one embodiment. Sputtering source 252 sputters material spray 254 toward the semiconductor feature 251 through the aperture 148. In the illustration of FIG. 2B, the semiconductor feature 251 is located to the left of the source 252, and deposition 256L is only grown on the left side of the semiconductor feature, as the left side of the semiconductor feature is covered by the top panel 142. In both cases, little to no material is deposited on the bottom of the semiconductor feature 251. The sputtering source 252 can be the target 188 as described above.

FIG. 3A illustrates a schematic side view of the support structure 250 with a substrate 310 disposed on the substrate support, according to one embodiment.

In some embodiments, the substrate 310 is a bare silicon, III-V, or germanium wafer. In another embodiment, the substrate 310 further includes a thin film. The substrate 310 can be a photomask, a semiconductor substrate, or other workpiece known to one of ordinary skill in the art of electronic device manufacturing. The substrate 310 includes any material to make any of integrated circuits, passive (e.g., capacitors, inductors) and active (e.g., transistors, photo detectors, lasers, diodes) microelectronic devices, according to some embodiments. The substrate 310 includes insulating (e.g., dielectric) materials that separate such active and passive microelectronic devices from a conducting layer or layers that are formed on top of them, according to one embodiment. In one embodiment, the substrate 310 is a semiconductor substrate that includes one or more dielectric layers, e.g., silicon dioxide, silicon nitride, sapphire, and other dielectric materials. In one embodiment, the substrate 310 is a substrate stack including one or more layers. The one or more layers of the substrate 310 can include conducting, semiconducting, insulating, or any combination thereof layers. The substrate 310 contains a plurality of features 251.

FIG. 3B illustrates a schematic side view of a portion of the halo 216, according to one embodiment. The halo 216 includes a halo flange 303, according to one embodiment. The halo flange 303 has a halo flange surface 303S, and the distance in the Z-direction between the halo flange surface 303S and the substrate support surface 212 is larger than the distance in the Z-direction between a halo surface 216S and the substrate support surface 212, where the Z-direction is substantially perpendicular to the X-direction. In some cases, due to the high velocities of the sputtered species, and due to the low angles of incidence upon the substrate 310 mandated by the shallow angle θ of the sloped portion 144, some of the sputtered species do not deposit on the substrate 310, but instead reflect and deposit on other portions of the chamber, which is known as redeposition. The smaller distance between the halo flange surface 303S and the top panel 142 allows for reflected sputtering species (path shown by arrow 301) to rapidly ricochet off the top panel, the halo surface 216S, and the halo flange surface 303S, forming redeposits 302. The redeposits 302 are thus formed on the halo flange surface 303S, the halo surface 216S, or on the bottom of top panel 142, rather than on the backside of the substrate 310, or on other components of the processing chamber 112, e.g., the actuators 220, 222 of the moveable substrate support 200.

The width W_{hf} of the halo flange 303 and the width Wₕ of the halo 216 is chosen such that the reflected sputtering species (path shown by arrow 301) ricochet off the bottom of the top panel 142, the halo surface 216S, or the halo flange surface 303S at least two times, which allows for a large amount of the reflected sputtering surfaces to form redeposits 302 on the halo flange surface and the bottom of the top panel. For example, for a vertical distance of about 2 mm to about 6 mm between the bottom of the top panel 142 and the halo flange surface 303S, and a deposition angle θ of about 20°, the width Wₕ of the halo 216 is about 40 mm, and the width W_{hf} of the halo flange 303 is about 20 mm.

FIG. 3C illustrates a schematic side view of a portion of the ring 214, according to one embodiment. The substrate support surface 212 includes a support rib 305 that supports a portion of the substrate 310. The support rib 305 allows the substrate 310 to bow, reducing strain in the substrate. The support rib 305 prevents wafer walking, so that the substrate 310 does not move during deposition. The ring 214 includes a gap 312 between the substrate 310 and the ring 214 that allows for reflected sputtering species to rapidly ricochet between the bottom of the substrate 310 and the ring 214. The redeposits 302 are thus formed in the gap 312, rather than on the substrate support surface 212, which reduces cleaning of the substrate support surface, and reduces cost of ownership of having to replace the substrate support surface. The support structure 250 is configured such that the substrate 310 is placed on the support rib 305, and thus the gap 312 is formed between the bottom of the substrate 310 and the ring 214. The ring 214 includes a ring groove 306 that allows for reflected sputtering species (path shown by arrow 301) to rapidly ricochet off the sides of the ring groove, forming redeposits 302. The redeposits 302 are thus formed in the ring groove 306, rather than on other components of the processing chamber 112, e.g., the actuators 220, 222 of the moveable substrate support 200. The geometry (depth and width) of the groove 306 protects the backside of the substrate 310 from formation of redeposits. The ratio of the depth to the width of the groove 306 is about 0.4 to about 1.5. For example, the groove 306 depth can be about 1.2 mm to about 5 mm, and the groove width can be about 0.8 mm to about 12.5 mm.

FIG. 3D illustrates a schematic side view of an interlocking system 304, according to one embodiment. As shown, the interlocking system 304 includes multiple halo side features 307, 308. The halo side features 307, 308 mechanically interlock such that reflected sputtering species (path shown by arrow 301) rapidly ricochet off of the halo side features, forming redeposits 302. Thus, the reflected sputtering species do not form unwanted redeposits in the machinery below. The interlocking system 304 can include any other type of mechanical or other interlocks, as long as the interlocking system prevents unwanted passage of the reflected sputtering species.

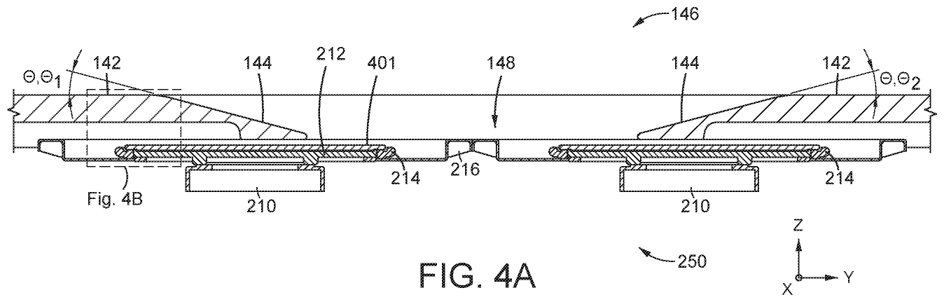

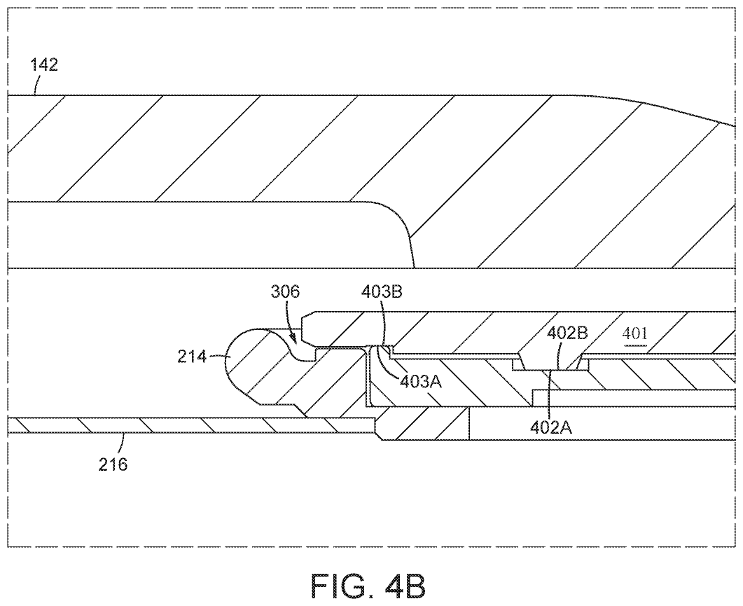

FIG. 4A illustrates a schematic side view of the support structure 250 with a shutter disk 401 disposed on the support structure, according to one embodiment. The shutter disk 401 is placed in the chamber 112 during a burn-in process, wherein the plurality of targets 188 are bombarded with plasma ions to remove oxides or other contaminants from the targets prior to performing substrate processes. The shutter disk 401 protects the support structure 250 from contaminants created during the burn-in process, which reduces cleaning of the substrate support surface 212, and reduces cost of ownership of having to periodically replace the substrate support surface. The shutter disk 401 is constructed of any suitable material having a mechanical stiffness sufficient enough to resist deformation due to the additional weight of materials which can be deposited atop the shutter disk. The material can also be lightweight so as to allow the shutter disk 401 to be easily maneuvered by a transfer robot. The shutter disk 401 can be stored inside of the chamber 112 in a shutter garage (not pictured), and the shutter disk can be transported by an internal chamber shutter feedthrough or single-axis robot. The shutter disk 401 can include aluminum (Al), aluminum alloys, aluminum silicon (AlSi) alloy, or other suitable material. The shutter disk 401 can be fabricated via any method suitable for forming the desired shape, for example, machining, extruding, stamping, mold casting, die casting, spray casting, spray deposition, or the like.

FIG. 4B illustrates a schematic side view of a portion of the substrate support surface 212, according to one embodiment. The support structure 250 is configured to alternately support a substrate 310 and a shutter disk 401, such that at least a portion of the support structure that is configured to contact the shutter disk, when the shutter disk is positioned on the support structure, does not contact the substrate when the substrate is positioned on the support structure, according to one embodiment. The portion of the substrate support surface 212 is a support area 402A, which is an indentation in the substrate support surface, according to one embodiment. The indentation can comprise an annular shape, according to one embodiment. The shutter disk 401 is manufactured such that a portion of the shutter disk 402B is placed in the support area 402A, but no other portion of the shutter disk rests on the substrate support surface 212. In contrast, the substrate 310 does not include a portion that fits in the support area 402A. In addition, the shutter disk 401 includes an indented portion 403B that does not touch the surface 403A of the support rib 305 of the ring 214. Thus, the substrate 310 and the shutter disk 401 do not touch the same portion of the substrate support surface 212 when the substrate and the shutter disk are alternately placed on the substrate support, which prevents the contamination of the backside of the substrate with material left behind from placing the shutter disk.

As described above, the support system 253 includes halos 216, and the halos protect the remainder of the processing chamber 112 from redeposition. The support structure 250 includes features such as a ring groove 306 and a gap 312 that trap reflected ions from sputtering, and ensure that residue is not formed in other components of the processing chamber 112 and on the backside of the substrate 310. The halos 216 interlock with one another using an interlocking system 304, which prevents sputtered material from entering gaps between the halos.

The halos 216 protect the machinery of the moveable substrate support 200 and other components of the processing chamber 112 from redeposition. The support structure 250 contains the support area 402A that prevents the shutter disk 401 and the substrate 310 do not touch the same portion of the substrate support, preventing cross-contamination between the shutter disk and the substrate.

While the foregoing is directed to implementations of the present invention, other and further implementations of the invention may be devised without departing from the basic scope thereof, and the scope thereof is determined by the claims that follow.

We claim:

1. A support system for use in a processing chamber, the support system comprising:
two support structures, each comprising;
a substrate support surface;
a ring, the substrate support surface surrounded by the ring; and
a halo, the halo at least partially surrounding the ring, the halo comprising a top surface and a halo flange comprising a halo flange surface, and a distance between the halo flange surface and the substrate support surface is greater than a distance between the top surface and the substrate support surface.

2. The support system of claim 1, wherein the support structures are each configured to alternately support a substrate and a shutter disk, such that at least a portion of the support structure that is configured to contact the shutter disk, when the shutter disk is positioned on the support structure, does not contact the substrate when the substrate is positioned on the support structure.

3. The support system of claim 1, wherein the halos are configured to interlock with one another via an interlocking system.

4. The support system of claim 3, wherein the interlocking system is configured such that reflected sputtering species ricochet at least two times within the interlocking system.

5. The support system of claim 1, wherein the ring further comprises a ring groove, and the support structure is configured to support a substrate positioned at least partially over the ring groove.

6. The support system of claim 5, wherein the support structure further comprises a support rib, and the support structure is configured to support a substrate on the support rib.

7. A moveable substrate support system, comprising:
two moveable substrate supports, each comprising:
a support structure, comprising:
a substrate support surface;
a ring, the substrate support surface surrounded by the ring; and
a halo, the halo at least partially surrounding the ring, the halo comprising a top surface and a halo flange comprising a halo flange surface, and the distance between a halo flange surface and the substrate support surface is greater than a distance between the top surface and the substrate support surface;
a robot arm, the robot arm connected to the support structure; and
a robot actuator connected to the robot arm, wherein the robot actuator is configured to move the robot arm and the support structure along a movement path.

8. The moveable substrate support system of claim 7, wherein the movement path is perpendicular to the top surface.

9. The moveable substrate support system of claim 8, wherein the movement path is approximately a straight line.

10. The moveable substrate support system of claim 7, wherein the support structure is configured to alternately support a substrate and a shutter disk, such that at least a portion of the support structure that is configured to contact the shutter disk, when the shutter disk is positioned on the support structure, does not contact the substrate when the substrate is positioned on the support structure.

11. The moveable substrate support system of claim 7, wherein the halos are configured to interlock with one another via an interlocking system.

12. The moveable substrate support system of claim 11, wherein the halos are interlocked with one another during at least a portion of the movement path.

13. The moveable substrate support system of claim 7, wherein the ring further comprises a ring groove, and the support structure is configured to support a substrate at least partially over the ring groove.

14. A processing chamber, comprising:
a moveable substrate support system, comprising:
two moveable substrate supports, each comprising:
a support structure, comprising:
a substrate support surface;
a ring, the substrate support surface surrounded by the ring; and
a halo, the halo at least partially surrounding the ring, the halo comprising a top surface and a halo flange comprising a halo flange surface, and the distance between a halo flange surface and the substrate support surface is greater than a distance between the top surface and the substrate support surface;
a robot arm, the robot arm connected to the support structure; and
a robot actuator connected to the robot arm, wherein the robot actuator is configured to move the robot arm and the substrate support surface along a movement path;
a top chamber surface having an aperture disposed therethrough;
one or more chamber walls; and
a chamber bottom, wherein an interior volume is at least partially bounded by the top chamber surface, one or more chamber walls, and the chamber bottom, the moveable substrate supports disposed within the interior volume.

15. The processing chamber of claim 14, wherein the substrate support surface is under the aperture for at least a portion of the movement path.

16. The processing chamber of claim 15, wherein the substrate support surface is not under the aperture for at least a portion of the movement path, and at least a portion of the halo is under the aperture for at least a portion of the movement path.

17. The processing chamber of claim 14, wherein the movement path is perpendicular to the top surface.

18. The processing chamber of claim 17, wherein the movement path is approximately a straight line.

19. The processing chamber of claim 14, wherein the top chamber surface comprises a top panel, the aperture disposed therethrough the top panel.

20. The processing chamber of claim 19, wherein at least a portion of the top panel is fluid cooled.
